(19) United States
(12) Patent Application Publication
(10) Pub. No.: US 2025/0057006 A1
(43) Pub. Date: Feb. 13, 2025

(54) UNDER-SCREEN CAMERA DISPLAY SCREEN AND DISPLAY DEVICE

(71) Applicant: HKC CORPORATION LIMITED, Shenzhen (CN)

(72) Inventors: Zhiwei YE, Shenzhen (CN); chen Chen, Shenzhen (CN); Xiufeng Zhou, Shenzhen (CN); Lidan Ye, Shenzhen (CN)

(21) Appl. No.: 18/789,740

(22) Filed: Jul. 31, 2024

(30) Foreign Application Priority Data
Aug. 8, 2023 (CN) 202310992659.9

(51) Int. Cl. H10K 59/65; G09G 3/3266; H10K 59/122; H10K 59/123; H10K 59/126

(52) U.S. Cl. CPC H10K 59/65; G09G 3/3266; H10K 59/122; H10K 59/123; H10K 59/126

(57) ABSTRACT

An under-screen camera display screen includes a display area and a non-display area. The display area includes an under-screen camera area. The non-display area includes at least one corner area. The under-screen camera area is disposed close to the corner area. The under-screen camera display screen includes a pixel circuit. The pixel circuit includes a first pixel circuit. The first pixel circuit is configured to drive the light-emitting device corresponding to the under-screen camera area to emit light. The first pixel circuit is disposed in the corner area that is close to the under-screen camera area. A display device is further provided.

### CROSS-REFERENCE TO RELATED APPLICATIONS

The present application claims priority to Chinese Patent Application No. 202310992659.9, entitled “UNDER-SCREEN CAMERA DISPLAY SCREEN AND DISPLAY DEVICE”, filed Aug. 8, 2023, which is herein incorporated by reference in its entirety.

### TECHNICAL FIELD

The present disclosure relates to the technical field of display, and in particular to an under-screen camera display screen and a display device.

### BACKGROUND

With the rapid advancement of display technology, front-facing cameras have become a barrier to pursuing high screen to body ratios. In related art, in order to achieve front-facing photography, compromise designs such as reducing camera area resolution, digging grooves, opening holes, disposing lifting cameras or the like are adopted.

However, the design of digging grooves or opening holes affects aesthetics and cannot achieve ultra-high screen to body ratio. An additional mechanical structure is required to support the lifting camera, which poses a risk of damage.

### SUMMARY OF THE DISCLOSURE

A first technical solution provided by the present disclosure is providing an under-screen camera display screen. The under-screen camera display screen includes a display area and a non-display area. The display area includes an under-screen camera area. The non-display area includes at least one corner area. The under-screen camera area is disposed close to the corner area. The under-screen camera display screen includes a pixel circuit.

The pixel circuit includes a first pixel circuit. The first pixel circuit is configured to drive a light-emitting device corresponding to the under-screen camera area to emit light.

The first pixel circuit is disposed in the corner area that is close to the under-screen camera area.

In some embodiments, the non-display area surrounds the display area, the non-display area further includes a side non-display area, and the corner area is disposed in a junction area of two adjacent side non-display areas.

In some embodiments, the corner area where the first pixel circuit is located is further configured to accommodate a gate driving circuit, and the gate driving circuit is configured to drive the display area.

In some embodiments, the pixel circuit further includes a second pixel circuit, and the display area further includes a non-under-screen camera area. The second pixel circuit is configured to drive the light-emitting device corresponding to the non-under-screen camera area to emit light.

In some embodiments, the under-screen camera area includes a plurality of under-screen pixel areas and a plurality of light-transmitting areas. Each of the plurality of light-transmitting areas is between the plurality of under-screen pixel areas, and each of the plurality of under-screen pixel areas corresponds to one light-emitting device.

In some embodiments, the under-screen camera display screen includes a driving substrate. The driving substrate includes a base, a first metal layer, a second metal layer, and a third metal layer. The first metal layer, the second metal layer, and the third metal layer are sequentially formed on a side of the base.

The first metal layer is configured to form a light-shielding metal layer.

The second metal layer is configured to form a first gate electrode and a second gate electrode that are insulated from each other.

The third metal layer is configured to form a first source electrode, a second source electrode, a first drain electrode, and a second drain electrode that are insulated from each other.

The first gate electrode, the first drain electrode, and the first source electrode are configured to form a driving transistor of the first pixel circuit. The driving transistor is configured to control current of the light-emitting device. The second gate electrode, the second source electrode, and the second drain electrode are configured to form a switching transistor of the first pixel circuit. In the first pixel circuit, the switching transistor is connected between the light-emitting device and the driving transistor.

An anode of the light-emitting device is connected to the second drain electrode of the switching transistor through a via lead layer. The via lead layer at least partially overlaps with the first source electrode of the driving transistor in a direction perpendicular to the base, so as to form a storage capacitor.

In some embodiments, the driving transistor is a top gate structure. The light-shielding metal layer is connected to the first gate electrode of the driving transistor and the first source electrode of the driving transistor, respectively, so as to form a double gate transistor.

In some embodiments, the under-screen camera display screen further includes a light-emitting device layer, and the light-emitting device layer is disposed on a side of the driving substrate away from the base. The light-emitting device layer includes a pixel definition layer, the light-emitting device, and a spacer. The pixel definition layer defines an opening. The light-emitting device is disposed in the opening. The spacer is disposed on a side of the pixel definition layer away from the base and avoids the opening.

The spacer includes a conductive layer and an insulation barrier layer disposed on a side of the conductive layer away from the base. A cathode of the light-emitting device is connected to the conductive layer.

In some embodiments, the light-emitting device is an organic light-emitting diode.

In some embodiments, the under-screen camera display screen is rectangular, the non-display area comprises four side non-display areas and four corner areas, and the first pixel circuit is disposed in one corner area.

A second technical solution provided by the present disclosure is providing a display device. The display device includes a camera module and the under-screen camera display screen of any one of above embodiments.

The under-screen camera display screen includes a light-output side and a non-light-output side that are opposite to each other. The camera module is disposed on the non-light-output side of the under-screen camera display screen and corresponds to the under-screen camera area.

### BRIEF DESCRIPTION OF THE DRAWINGS

In order to more clearly illustrate the technical solutions in some embodiments of the present disclosure, hereinafter, a brief introduction will be given to the accompanying drawings that are used in the description of some embodiments. Obviously, the accompanying drawings in the description below are merely some embodiments of the present disclosure. For those of ordinary skill in the art. other accompanying drawings may be obtained based on these accompanying drawings without any creative efforts.

FIG. 1 is a structural schematic view of an under-screen camera display screen in some embodiments of the present disclosure.

FIG. 2 is an enlarged structural schematic view of A part in FIG. 1.

FIG. 3 is a partial structural schematic view of pixel arrangement in some embodiments of the present disclosure.

FIG. 4 is an enlarged structural schematic view of H part in FIG. 3.

FIG. 5 is an enlarged structural schematic view of K part in FIG. 3.

FIG. 6 is a longitudinal cross-sectional structural schematic view of an array substrate and a pixel device layer in some embodiments of the present disclosure.

FIG. 7 is a structural schematic view of a first pixel circuit in some embodiments of the present disclosure.

FIG. 8 is a structural schematic view of a display device in some embodiments of the present disclosure.

### DETAILED DESCRIPTION

The technical solutions in the embodiments of the present disclosure may be explained in detail by combining the accompanying drawings.

In the following description, specific details such as specific system structures, interfaces, technologies, etc. are proposed for the purpose of illustration rather than limitation, so as to fully understand the present disclosure.

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe purposes and cannot be understood as indicating or implying relative importance or implicit indicating the quantity of technical features indicated. Therefore, features limited to “first”, “second”, and “third” may explicitly or implicitly include at least one of these features. In the description of the present disclosure, “multiple” means at least two, such as two, three, etc., unless otherwise expressly and specifically qualified. All directional indications (such as up, down, left, right, front, rear, or the like) in some embodiments of the present disclosure are only configured to explain a relative position relationship between components in a specific posture (as shown in the accompanying drawings), a motion situation between the components in the specific posture (as shown in the accompanying drawings), or the like. If the specific posture is changed, the directional indication is also changed accordingly. In addition, the terms “including”, “comprising”, and “having”, as well as any variations of the terms “including”, “comprising”, and “having”, are intended to cover non-exclusive inclusions. For example, a process, method, system, product, or device that includes a series of operations or units is not limited to the listed operations or units, but optionally includes operations or units that are not listed, or optionally includes other operations or units that are inherent to these processes, methods, products, or devices.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure may be combined with other embodiments.

A main technical problem solved by the present disclosure is that a front-facing camera is difficult to have a high screen to body ratio. Thus, the present disclosure provides an under-screen camera display screen and a display device, which may solve the problem that the front-facing camera is difficult to have the high screen to body ratio.

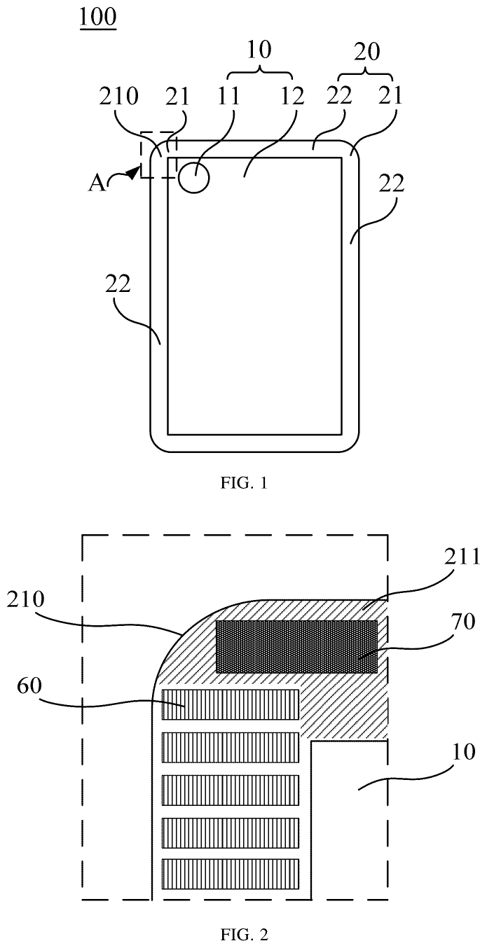

As illustrated in FIG. 1 and FIG. 2, FIG. 1 is a structural schematic view of an under-screen camera display screen in some embodiments of the present disclosure, and FIG. 2 is an enlarged structural schematic view of A part in FIG. 1.

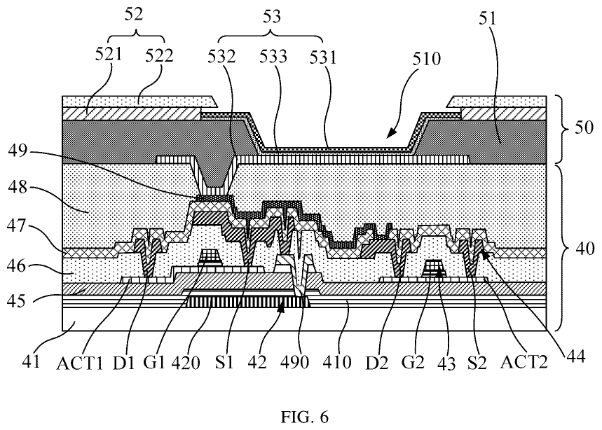

The present provides an under-screen camera display screen 100. The under-screen camera display screen 100 includes a display area 10 and a non-display area 20. The display area 10 includes an under-screen camera area 11, and the non-display area 20 includes at least one corner area 21. The under-screen camera area 11 is disposed close to one of the at least one corner area 21. The under- screen camera display screen 100 includes a pixel circuit, and the pixel circuit includes a first pixel circuit 70. The first pixel circuit 70 is configured to drive the light-emitting device 53 (as shown in FIG. 6) corresponding to the under-screen camera area 11 to emit light. The first pixel circuit 70 is disposed in the corner area 21 that is close to the under-screen camera area 11. In the present disclosure, the first pixel circuit 70 that is configured to drive the light-emitting device 53 corresponding to the under-screen camera area 11 to emit light is disposed in the corner area 21 of the non-display area 20, and the remaining space in the corner area 21 is configured to accommodate the first pixel circuit 70, thereby avoiding the first pixel circuit 70 from occupying an area of the under-screen camera area 11. Thus, the light transmittance of the under-screen camera area 11 is improved, thereby enabling the under-screen camera area 11 to have dual functions of light-transmission and display, and increasing the screen to body ratio of the under-screen camera display screen 100.

The non-display area 20 surrounds the display area 10. The non-display area 20 further includes side non-display areas 22. The corner area 21 is disposed in a junction area between two adjacent side non-display areas 22. Each of the side non-display areas 22 is disposed on a side of the display area 10.

In some embodiments, the non-display area 20 is disposed around the display area 10. The under-screen camera display screen 100 is rectangular. That is, the non-display area 20 includes four side non-display areas 22 and four corner areas 21. The first pixel circuit 70 is disposed in one corner area 21. A first corner area 210 is disposed in an upper left corner of the under-screen camera display screen 100.

The first corner area 210 may be disposed in any of an upper right corner, a bottom left corner, or a bottom right corner of the under-screen camera display screen 100, and may be selected according to actual needs.

The corner area 21 where the first pixel circuit 70 is located is further configured to accommodate a gate driving circuit (not shown in the figures) that is configured for driving the display area 10. One end of the first pixel circuit 70 connected to the light-emitting device 53 is introduced into the display area 10 through a lead and connected to the light-emitting device 53.

The gate driving circuit includes a cascaded effective GOA (Gate Driven on Array) unit 60 (also known as an effective gate driving circuit) and a virtual GOA unit (i.e. Dummy GOA unit, also known as a virtual gate driving circuit). The effective GOA unit 60 is connected to a gate line (not shown in the figures) disposed in the display area 10, while the virtual GOA unit is not connected to the gate line, resulting in different loads for the effective GOA unit 60 and the virtual GOA unit. In related art, in addition to setting up effective GOA units 60, the corner area 21 further includes an additional wiring space 211. The additional wiring space 211 is generally filled with the virtual GOA units.

In the present disclosure, a normal layout of the effective GOA units 60 in the corner area 21 is retained, the virtual GOA units filled in the additional wiring space 211 are removed, and the first pixel circuit 70 is disposed in the additional wiring space 211 of the corner area 21. On the premise of not affecting the normal function of the gate driving circuit in the corner area 21, the first pixel circuit 70 avoids occupying the area of the under-screen camera area 11, thereby improving the light transmittance of the under-screen camera area 11 and increasing the screen to body ratio of the under-screen camera display screen 100.

The pixel circuit further includes a second pixel circuit (not shown in the figures), and the display area 10 further includes a non-under-screen camera area 12. The second pixel circuit is configured to drive the light-emitting device 53 corresponding to the non-under-screen camera area 12 to emit light. The second pixel circuit corresponds to the non-under-screen camera area 12, that is, the second pixel circuit is located below the non-under-screen camera area 12.

A structure of the first pixel circuit 70 may be the same as or different from a structure of the second pixel circuit. The structure of the first pixel circuit 70 and the structure of the second pixel circuit are not limited, and may be selected according to actual needs.

The non-under-screen camera area 12 is a normal display area of the under-screen camera display screen 100. The use of a front-facing camera function does not affect the display of the images in the non-under-screen camera area 12. The under-screen camera area 11 does not display the images when using the front-facing camera function.

In the present disclosure, the under-screen camera area 11 is disposed close to the first corner area 210. The under-screen camera area 11 is disposed in the upper left corner area. A shape and a size of the under-screen camera area 11 are not limited, and may be selected according to actual needs.

In response to the under-screen camera area 11 being close to the first corner area 210, the under-screen camera area 11 may also be disposed in a middle area between the upper left corner and the upper right corner, and disposed close to the upper left corner area. The under-screen camera area 11 may also be disposed in a middle area between the upper left corner and the bottom left corner, and disposed close to the upper left corner area. As long as the under-screen camera area 11 is disposed close to the corner area 21 where the first pixel circuit 70 is located, so as to reduce wiring.

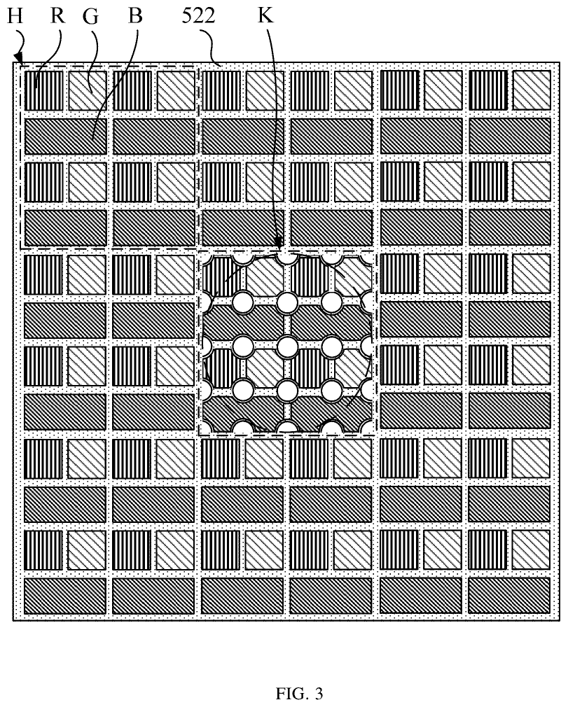

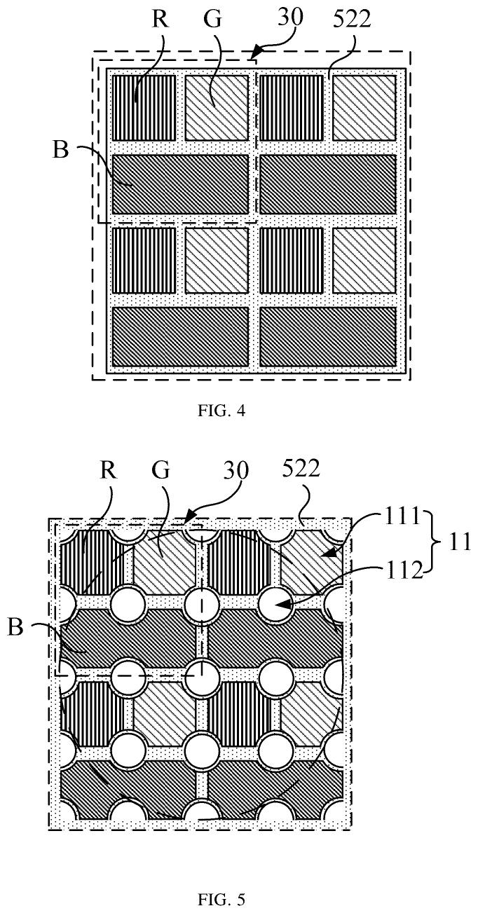

As illustrated in FIG. 1 to FIG. 5, FIG. 3 is a partial structural schematic view of pixel arrangement in some embodiments of the present disclosure, FIG. 4 is an enlarged structural schematic view of H part in FIG. 3, and FIG. 5 is an enlarged structural schematic view of K part in FIG. 3.

The under-screen camera area 11 includes multiple under-screen pixel areas 111 and multiple light-transmitting areas 112, and each light-transmitting area 112 is disposed between the under-screen pixel areas 111. The under-screen pixel area 111 corresponds to the light-emitting device 53. The under-screen pixel area 111 is configured to accommodate pixels, so as to display the images when not using the front-facing camera function. The light-transmission area 112 is configured to transmit external light when using the front-facing camera function. Thus, the under-screen camera area 11 has dual functions of light-transmission and display, thereby achieving normal display of the under-screen camera area 11 and improving the screen to body ratio of the under-screen camera display screen 100.

Taking a pixel layout of the display area 10 as an example, the pixel layouts of the under-screen camera area 11 and the non-under-screen camera area 12 may be explained below.

The non-under-screen camera area 12 includes three pixels with different colors, namely red pixel R, blue pixel B, and green pixel G. One red pixel R, one blue pixel B, and one green pixel G forms one pixel unit 30. The pixel units 30 are arranged in an array. In each pixel unit 30, the red pixel R and green pixel G are disposed side by side on the same side of the blue pixel B. An insulation barrier layer 522 is disposed between pixels. The pixel layout of the under-screen camera area 11 is the same as that of the non-under-screen camera area 12. Based on this, as illustrated in FIG. 5, the under-screen camera area 11 further includes the light-transmitting area 112 that is located between the under-screen pixel areas 111. The light-transmitting area 112 may sacrifice some pixel space, thereby reducing a light-emitting area of each pixel of the pixel unit 30. A pixel density of the under-screen camera area 11 is less than that of the non-under-screen camera area 12. A distribution, a shape, and a size of the light-transmitting area 112 not limited, and may be selected according to actual needs. A circular dashed line in FIG. 5 represents a position of a camera module 200 (as shown in FIG. 8). The under-screen camera display screen 100 does not include the camera module 200.

A pixel layout structure of the display area 10 in the present disclosure includes but is not limited to above pixel layout. The under-screen camera display screen 100 of the present disclosure is suitable for various pixel layout structures in related art.

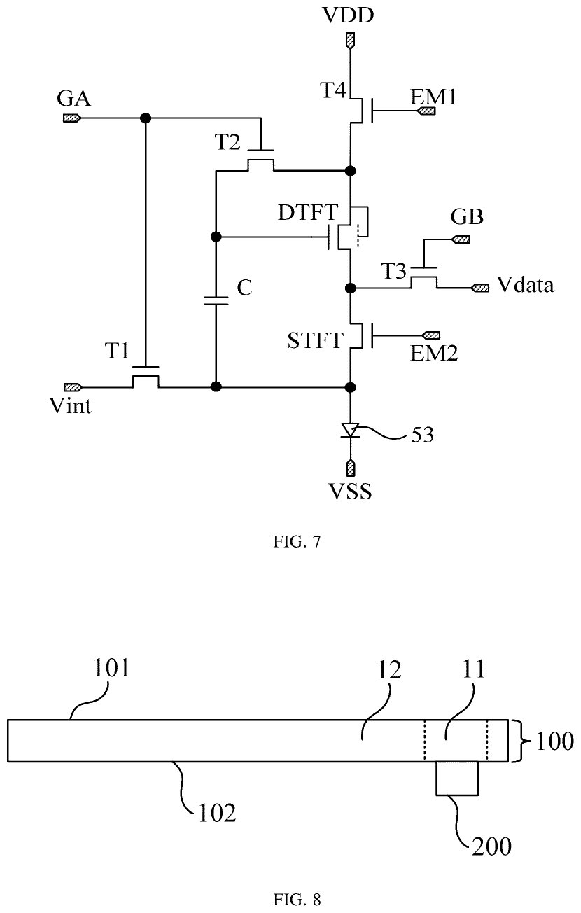

As illustrated in FIG. 2, FIG. 6, and FIG. 7, FIG. 6 is a longitudinal cross-sectional structural schematic view of an array substrate and a pixel device layer in some embodiments of the present disclosure, and FIG. 7 is a structural schematic view of a first pixel circuit in some embodiments of the present disclosure.

As illustrated in FIG. 6, the under-screen camera display screen 100 includes a driving substrate 40. The driving substrate 40 includes a base 41, a first metal layer 42, a second metal layer 43, and a third metal layer 44. The first metal layer 42, the second metal layer 43, and the third metal layer 44 are sequentially formed on a side of the base 41.

The first metal layer 42 is configured to form a light-shielding metal layer 420.

The second metal layer 43 is configured to form a first gate electrode G1 and a second gate electrode G2 that are insulated from each other.

The third metal layer 44 is configured to form a first source electrode S1, a second source electrode S2, a first drain electrode D1, and a second drain electrode D2 that are insulated from each other.

The first gate electrode G1, the first drain electrode D1, and the first source electrode S1 are configured to form a driving transistor DTFT of the first pixel circuit 70. The driving transistor DTFT is configured to control current of the light-emitting device 53. The second gate electrode G2, the second source electrode S2, and the second drain electrode D2 are configured to form a switching transistor STFT of the first pixel circuit 70. In the first pixel circuit 70, the switching transistor STFT is connected between the light-emitting device 53 and the driving transistor DTFT. An anode 532 of the light-emitting device 53 is connected to the second drain electrode D2 of the switching transistor STFT through a via lead layer 49. The via lead layer 49 at least partially overlaps with the first source electrode S1 of the driving transistor DTFT in a direction perpendicular to the base 41, so as to form a storage capacitor C.

The driving transistor DTFT is a top gate structure, and the driving transistor DTFT further includes an active layer ACT1. The light-shielding metal layer 420 is disposed on a bottom of the driver transistor DTFT. When using the front-facing camera function, the light-shielding metal layer 420 may shield or block scattered light from the camera, thereby protecting the performance of the driver transistor DTFT from being affected by light.

In some embodiments, the switching transistor STFT is also the top gate structure, and the switching transistor STFT further includes an active layer ACT2. The light-shielding metal layer 420 is connected to the first gate electrode G1 of the driving transistor DTFT and the first source electrode S1 of the driving transistor DTFT, respectively, to form a double gate transistor. In some embodiments, the light-shielding metal layer 420 is connected to the first source electrode S1 of the driving transistor DTFT through a via lead 490. The first gate electrode G1, the first drain electrode D1, the first source electrode S1, and the light-shielding metal layer 420 form the double gate transistor. That is, the driving transistor DTFT in the first pixel circuit 70 is the double gate transistor, and the light-shielding metal layer 420 is used as a bottom gate electrode. That is, a self-generated bottom gate electrode is used in an edge area of the camera to shield or block the scattered light of the camera, so as to protect the performance of the driving transistor DTFT from being affected by the light. The disposing of the light-shielding metal layer 420 may not only provide a light-shielding and protecting function, but also form the double gate transistor, thereby improving using performance of the driving transistor DTFT and enhancing the light-emitting performance of the light-emitting device 53.

In some embodiments, the light-shielding metal layer 420 may be independently disposed without conducting with the first source electrode S1 and the first gate electrode G1, and the light-shielding metal layer 420 only serves as the light-shielding and protecting function.

The driving substrate 40 further includes an insulation layer 410, a buffer layer 45, an interlayer dielectric layer 46, a passivation layer 47, and a planarization layer 48. The insulation layer 410, the buffer layer 45, the interlayer dielectric layer 46, the passivation layer 47, and the planarization layer 48 are sequentially formed on the side of the base 41. The insulation layer 410 covers the first metal layer 42, the buffer layer 45 is disposed between the insulation layer 410 and the second metal layer 43, and the interlayer dielectric layer 46 is disposed between the second metal layer 43 and the third metal layer 44. The insulation layer 410 and the buffer layer 45 may be made of the same material and prepared in one process. Alternatively, the insulation layer 410 and the buffer layer 45 may be made of different materials. The materials of the insulation layer 410 and the buffer layer 45 are not limited, and may be selected according to actual needs. The passivation layer 47 and the planarization layer 48 are sequentially stacked on the side of the third metal layer 44 away from the base 41. The via lead layer 49 is disposed between the passivation layer 47 and the planarization layer 48. The anode 532 of the light-emitting device 53 passes through the planarization layer 48 and is connected to the via lead layer 49. The materials of the insulation layer 410, the buffer layer 45, the interlayer dielectric layer 46, the passivation layer 47, and the planarization layer 48 are not limited, and may be selected according to actual needs.

The under-screen camera display screen 100 further includes a light-emitting device layer 50, and the light-emitting device layer 50 is located on a side of the driving substrate 40 away from the base 41. The light-emitting device layer 50 includes a pixel definition layer 51, a spacer 52, and a light-emitting device 53. The pixel definition layer 51 defines an opening 510, and the light-emitting device 53 is located in the opening 510. The spacer 52 is disposed on a side of the pixel definition layer 51 away from the base 41 and avoids the opening 510. That is, the spacer 52 is spaced apart from the opening 510. The spacer 52 includes a conductive layer 521 and an insulation barrier layer 522, and the insulation barrier layer 522 is located on a side of the conductive layer 521 away from the base 41. A cathode 531 of the light-emitting device 53 is connected to the conductive layer 521. The light-emitting device 53 further includes a light-emitting layer 533 located between the cathode 531 and the anode 532. The pixels are disposed between the insulation barrier layers 522, and the pixels are facing the opening 510.

In the present disclosure, the spacer 52 is disposed, which is different from a full surface evaporation process of a fine metal mask (FMM). In the process of preparing the cathode 531, there is no need to a laser process to pattern the cathode 531, which may simplify the process.

The light-emitting device 53 is an organic light-emitting diode (OLED).

The first pixel circuit 70 is taken as an example for explanation.

As illustrated in FIG. 7, the first pixel circuit 70 not only includes the driving transistor DTFT and the switching transistor STFT, but also includes a first transistor T1, a second transistor T2, a third transistor T3, a fourth transistor T4, and a capacitor C. A control terminal of the first transistor T1 and a control terminal of the second transistor T2 are connected to a first control signal GA. The first transistor T1 is configured to be connected to an initial signal Vint, so as to reset the first pixel circuit 70. The third transistor T3 is configured to respond to the second control signal GB and be connected to a data voltage, so as to charge capacitor C. The fourth transistor T4 is configured to respond to a first light-emitting control signal EM1 and be connected to the power supply voltage VDD. A control terminal (i.e., the second gate electrode G2) of the switching transistor STFT is connected to a second light-emitting control signal EM2. The cathode 531 of the light-emitting device 53 is connected to the low potential signal line VSS. A specific circuit connection relationship of the first pixel circuit 70 is illustrated in FG. 7, which is not described in detail here.

The first pixel circuit 70 of the present disclosure includes but is not limited to above structure.

In some embodiments, in the first pixel circuit 70, the driving transistor DTFT is a four-terminal device, all other transistors are three-terminal devices. The four-terminal device refers to the double gate transistor. The transistors are oxide thin film transistors. A turn-on speed of the driving transistor DTFT in some embodiments is relatively slow, and a subthreshold swing (SS) is larger, which is beneficial for grayscale expansion. The other transistors have faster turn-on speeds and larger switching ratios, thus, other transistors are suitable to use as switching devices.

In some embodiments, at least one of the remaining transistors is the four-terminal device.

The present disclosure provides the under-screen camera display screen 100. The under-screen camera display screen 100 includes the display area 10 and the non-display area 20. The display area 10 includes the under-screen camera area 11. The non-display area 20 includes at least one corner area 21. The under-screen camera area 11 is disposed close to the corner area 21. The under-screen camera display screen 100 includes the pixel circuit. The pixel circuit includes a first pixel circuit 70. The first pixel circuit 70 is configured to drive the light-emitting device 53 corresponding to the under-screen camera area 11 to emit light. The first pixel circuit 70 is disposed in the corner area 21 that is close to the under-screen camera area 11. In the present disclosure, the first pixel circuit 70 that drives the light-emitting device 53 corresponding to the under-screen camera area 11 to emit light is disposed in the corner area 21 of the non-display area 20. That is, the remaining space in the corner area 21 is configured to accommodate the first pixel circuit 70, thereby avoiding the first pixel circuit 70 from occupying an area of the under-screen camera area 11. Thus, the light transmittance of the under-screen camera area 11 is improved, thereby enabling the under-screen camera area 11 to have dual functions of light-transmission and display, and increasing the screen to body ratio of the under-screen camera display screen 100.

As illustrated in FIG. 8, FIG. 8 is a structural schematic view of a display device in some embodiments of the present disclosure.

The present disclosure provides a display device, and the display device includes the camera module 200 and the under-screen camera display screen 100 as described above.

The under-screen camera display screen 100 includes the light-output side 101 and the non-light-output side 102, and the light-output side 101 is opposite to the non-light-output side 102. The camera module 200 is disposed on the non-light-output side 102 of the under-screen camera display screen 100, and corresponds to the under-screen camera area 11.

The camera module 200 includes a camera. The camera is a front-facing camera. When using the camera, the under-screen camera area 11 does not display, thereby allowing the camera to take pictures. When the camera is not used, the under-screen camera area 11 may display. Thus, on the premise of retaining the camera function, the screen to body ratio may be increased.

Different from the related art, the effects of the present disclosure are as follows. The present disclosure provides the under-screen camera display screen and the display device. The under-screen camera display screen includes the display area and the non-display area. The display area includes the under-screen camera area. The non-display area includes at least one corner area. The under-screen camera area is disposed close to the corner area. The under-screen camera display screen includes the pixel circuit. The pixel circuit includes a first pixel circuit. The first pixel circuit is configured to drive the light-emitting device corresponding to the under-screen camera area to emit light. The first pixel circuit is disposed in the corner area that is close to the under-screen camera area. In the present disclosure, the first pixel circuit that drives the light-emitting device corresponding to the under-screen camera area to emit light is disposed in the corner area of the non-display area. That is, the remaining space in the corner area is configured to accommodate the first pixel circuit, thereby avoiding the first pixel circuit from occupying an area of the under-screen camera area. Thus, the light transmittance of the under-screen camera area is improved, thereby enabling the under-screen camera area to have dual functions of light-transmission and display, and increasing the screen to body ratio of the under-screen camera display screen.

The above descriptions are only some embodiments of the present disclosure, and are not intended to limit the scope of the present disclosure. Any equivalent structure or equivalent flow transformation made by using the contents of the specification and accompanying drawings of the present disclosure, or directly or indirectly applied to other related technical fields, is included in the scope of the patent protection of the present disclosure.

What is claimed is:

1. An under-screen camera display screen, comprising:
a display area comprising an under-screen camera area;
a non-display area comprising at least one corner area; wherein the under-screen camera area is disposed close to one of the at least one corner area; and
a pixel circuit comprising a first pixel circuit, wherein the first pixel circuit is configured to drive a light-emitting device corresponding to the under-screen camera area to emit light, and the first pixel circuit is disposed in the corner area that is close to the under-screen camera area.

2. The under-screen camera display screen according to claim 1, wherein the non-display area surrounds the display area, the non-display area further comprises side non-display areas, and the corner area is disposed in a junction area of two adjacent side non-display areas.

3. The under-screen camera display screen according to claim 2, wherein the corner area where the first pixel circuit is located is further configured to accommodate a gate driving circuit, and the gate driving circuit is configured to drive the display area.

4. The under-screen camera display screen according to claim 1, wherein the pixel circuit further comprises a second pixel circuit, the display area further comprises a non-under-screen camera area, the second pixel circuit is configured to drive the light-emitting device corresponding to the non-under-screen camera area to emit light.

5. The under-screen camera display screen according to claim 1, wherein the under-screen camera area comprises a plurality of under-screen pixel areas and a plurality of light-transmitting areas, each of the plurality of light-transmitting areas is between the plurality of under-screen pixel areas, and each of the plurality of under-screen pixel areas corresponds to one light-emitting device.

6. The under-screen camera display screen according to claim 1, wherein the under-screen camera display screen comprises a driving substrate; the driving substrate comprises a base, a first metal layer, a second metal layer, and a third metal layer; the first metal layer, the second metal layer, and the third metal layer are sequentially formed on a side of the base;
the first metal layer is configured to form a light-shielding metal layer;
the second metal layer is configured to form a first gate electrode and a second gate electrode that are insulated from each other;
the third metal layer is configured to form a first source electrode, a second source electrode, a first drain electrode, and a second drain electrode that are insulated from each other;
the first gate electrode, the first drain electrode, and the first source electrode are configured to form a driving transistor of the first pixel circuit, and the driving transistor is configured to control current of the light-emitting device; the second gate electrode, the second source electrode, and the second drain electrode are configured to form a switching transistor of the first pixel circuit; in the first pixel circuit, the switching transistor is connected between the light-emitting device and the driving transistor; and
an anode of the light-emitting device is connected to the second drain electrode of the switching transistor through a via lead layer, and the via lead layer at least partially overlaps with the first source electrode of the driving transistor in a direction perpendicular to the base, so as to form a storage capacitor.

7. The under-screen camera display screen according to claim 6, wherein the driving transistor is a top gate structure, and the light-shielding metal layer is connected to the first gate electrode of the driving transistor and the first source electrode of the driving transistor, respectively, so as to form a double gate transistor.

8. The under-screen camera display screen according to claim 7, further comprising a light-emitting device layer, wherein the light-emitting device layer is disposed on a side of the driving substrate away from the base, and the light-emitting device layer comprises:
a pixel definition layer, defining an opening;
the light-emitting device, disposed in the opening; and
a spacer, disposed on a side of the pixel definition layer away from the base and avoiding the opening; wherein the spacer comprises a conductive layer and an insulation barrier layer disposed on a side of the conductive layer away from the base, and a cathode of the light-emitting device is connected to the conductive layer.

9. The under-screen camera display screen according to claim 1, wherein the light-emitting device is an organic light-emitting diode.

10. The under-screen camera display screen according to claim 1, wherein the under-screen camera display screen is rectangular, the non-display area comprises four side non-display areas and four corner areas, and the first pixel circuit is disposed in one corner area.

11. A display device, comprising:
a camera module; and
an under-screen camera display screen, comprising:
a display area comprising an under-screen camera area;
a non-display area comprising at least one corner area; wherein the under-screen camera area is disposed close to one of the at least one corner area;
a pixel circuit comprising a first pixel circuit, wherein the first pixel circuit is configured to drive a light-emitting device corresponding to the under-screen camera area to emit light, and the first pixel circuit is disposed in the corner area that is close to the under-screen camera area;
a light-output side; and
a non-light-output side, wherein the light-output side and non-light-output side are opposite to each other, and the camera module is disposed on the non-light-output side of the under-screen camera display screen and corresponds to the under-screen camera area.

12. The display device according to claim 11, wherein the non-display area surrounds the display area, the non-display area further comprises a side non-display area, and the corner area is disposed in a junction area of two adjacent side non-display areas.

13. The display device according to claim 12, wherein the corner area where the first pixel circuit is located is further configured to accommodate a gate driving circuit, and the gate driving circuit is configured to drive the display area.

14. The display device according to claim 11, wherein the pixel circuit further comprises a second pixel circuit, the display area further comprises a non-under-screen camera area, the second pixel circuit is configured to drive the light-emitting device corresponding to the non-under-screen camera area to emit light.

15. The display device according to claim 11, wherein the under-screen camera area comprises a plurality of under-screen pixel areas and a plurality of light-transmitting areas, each of the plurality of light-transmitting areas is between the plurality of under-screen pixel areas, and each of the plurality of under-screen pixel areas corresponds to one light-emitting device.

16. The display device according to claim 11, wherein the under-screen camera display screen comprises a driving substrate; the driving substrate comprises a base, a first metal layer, a second metal layer, and a third metal layer; the first metal layer, the second metal layer, and the third metal layer are sequentially formed on a side of the base;
the first metal layer is configured to form a light-shielding metal layer;
the second metal layer is configured to form a first gate electrode and a second gate electrode that are insulated from each other;
the third metal layer is configured to form a first source electrode, a second source electrode, a first drain electrode, and a second drain electrode that are insulated from each other;
the first gate electrode, the first drain electrode, and the first source electrode are configured to form a driving transistor of the first pixel circuit, and the driving transistor is configured to control current of the light-emitting device; the second gate electrode, the second source electrode, and the second drain electrode are configured to form a switching transistor of the first pixel circuit; in the first pixel circuit, the switching transistor is connected between the light-emitting device and the driving transistor; and
an anode of the light-emitting device is connected to the second drain electrode of the switching transistor through a via lead layer, and the via lead layer at least partially overlaps with the first source electrode of the driving transistor in a direction perpendicular to the base, so as to form a storage capacitor.

17. The display device according to claim 16, wherein the driving transistor is a top gate structure, and the light-shielding metal layer is connected to the first gate electrode of the driving transistor and the first source electrode of the driving transistor, respectively, so as to form a double gate transistor.

18. The display device according to claim 17, the under-screen camera display screen further comprises a light-emitting device layer, wherein the light-emitting device layer is disposed on a side of the driving substrate away from the base, and the light-emitting device layer comprises:
a pixel definition layer, defining an opening;
the light-emitting device, disposed in the opening; and
a spacer, disposed on a side of the pixel definition layer away from the base and avoiding the opening; wherein the spacer comprises a conductive layer and an insulation barrier layer disposed on a side of the conductive layer away from the base, and a cathode of the light-emitting device is connected to the conductive layer.

19. The display device according to claim 11, wherein the light-emitting device is an organic light-emitting diode.

20. The display device according to claim 11, wherein the under-screen camera display screen is rectangular, the non-display area comprises four side non-display areas and four corner areas, and the first pixel circuit is disposed in one corner area.
